(19) United States
(12) Patent Application Publication
(10) Pub. No.: US 2025/0063715 A1
(43) Pub. Date: Feb. 20, 2025

(54) SEMICONDUCTOR MEMORY STRUCTURE AND METHOD FOR FORMING THE SAME

(71) Applicant: Winbond Electronics Corp., Taichung City (TW)

(72) Inventors: Ji-Min LIN, Tainan City (TW); Pin-Hung CHEN, Tainan City (TW)

(21) Appl. No.: 18/651,792

(22) Filed: May 1, 2024

(30) Foreign Application Priority Data
Aug. 15, 2023 (TW) 112130626

(51) Int. Cl. H10B 12/00; H01L 21/28

(52) U.S. Cl. CPC H10B 12/03; H01L 21/28185; H01L 21/28194; H01L 28/75; H10B 12/482

(57) ABSTRACT

A method for forming a semiconductor memory structure includes forming a bottom electrode layer over an active region, depositing a first high-k dielectric material on the bottom electrode layer, depositing a second high-k dielectric material on the first high-k dielectric material, annealing the first and second high-k dielectric materials, after the annealing process, depositing a third high-k dielectric material on the second high-k dielectric material, and forming a top electrode layer on the third high-k dielectric material.

### CROSS REFERENCE TO RELATED APPLICATIONS

This application claims the benefit of Taiwan Patent Application No. 112130626 filed on Aug. 15, 2023, entitled “SEMICONDUCTOR MEMORY STRUCTURE AND METHOD FOR FORMING THE SAME” which is hereby incorporated herein by reference.

### BACKGROUND

### Field of the Disclosure

The present disclosure relates to a semiconductor memory structure and a method for forming the same, and in particular, it relates to dynamic random access memory and a method for forming the same.

### Description of the Related Art

In order to increase the component density within Dynamic Random Access Memory (DRAM) devices and enhance their overall performance, current manufacturing techniques for DRAM devices are continually striving towards the miniaturization of component sizes. Therefore, improving the manufacturing methods of DRAM devices is a crucial challenge that must be addressed at present.

### SUMMARY

The method of forming a semiconductor memory structure includes forming a bottom electrode layer over the active region, depositing a first high-k dielectric material on the bottom electrode layer, depositing a second high-k dielectric material on the first high-k dielectric material, annealing the first and second high-k dielectric materials, after the annealing process, depositing a third high-k dielectric material on the second high-k dielectric material, and forming a top electrode layer on the third high-k dielectric material.

The semiconductor memory structure includes a transistor disposed over a substrate, a bottom electrode layer disposed over the transistor and electrically connected to a first source/drain region of the transistor, and a capacitor dielectric film. The capacitor dielectric film includes, sequentially disposed over the bottom electrode layer, a first high-k dielectric material, a second high-k dielectric material, and a third high-k dielectric material. Grains of the first high-k dielectric material have a first average size, grains of the third high-k dielectric material have a second average size, and the first average size is greater than the second average size. This semiconductor memory structure also includes a top electrode layer disposed above the capacitor dielectric film.

### BRIEF DESCRIPTION OF THE DRAWINGS

In accordance with some embodiments of the present disclosure, it may be further understood by reading the subsequent detailed description and examples with references made to the accompanying drawings, wherein:

FIG. 1A is a plan view illustrating a semiconductor memory structure, in accordance with some embodiments.

FIG. 1B is a cross-sectional view illustrating a semiconductor memory structure, in accordance with some embodiments.

FIGS. 2-5 and FIG. 7 are cross-sectional views illustrating the formation of a semiconductor memory structure at various intermediate stages, in accordance with some embodiments.

FIGS. 6A-6C are schematic diagrams illustrating the details of the formation of a capacitance dielectric film, in accordance with some embodiments.

### DETAILED DESCRIPTION

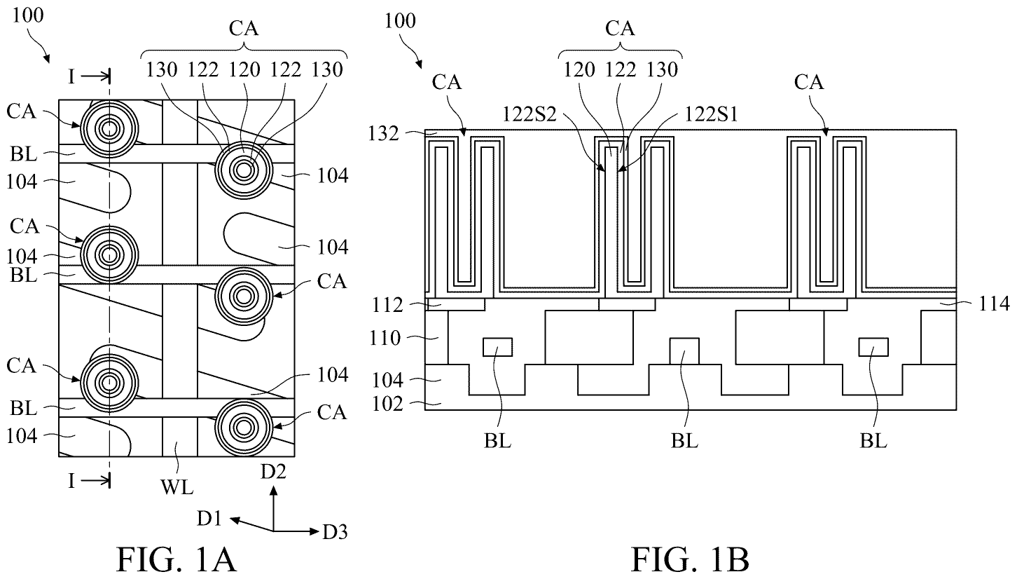

FIGS. 1A and 1B are respectively a plan view and a cross-sectional view illustrating a semiconductor memory structure 100, where FIG. 1B corresponds to line I-I in FIG. 1A. For clarity, FIG. 1A only shows some components of the semiconductor memory structure 100, while other components of the semiconductor memory structure 100 may be seen in FIG. 1B.

A semiconductor memory structure 100 is provided, which may be or include a dynamic random-access memory (DRAM) device. The semiconductor memory structure 100 includes a substrate 102. The substrate 102 may be or include a semiconductor substrate, which may be an elemental semiconductor substrate (such as a silicon substrate) or a compound semiconductor substrate.

For ease of illustration, FIG. 1A indicates a reference direction. Directions D1, D2, and D3 are horizontal directions. The second direction D2 is substantially perpendicular to the third direction D3. The first direction D1 intersects the second direction D2 at an acute angle. Line I-I is parallel to the second direction D2.

The semiconductor memory structure 100 further includes multiple active regions 104, which extend in the first direction D1. Each of the active regions 104 may be defined as multiple channel regions and multiple source/drain regions, with the alternating channel regions and source/drain regions arranged in the first direction D1. For example, two first source/drain regions are located in the two end portions of the active region 104, and one second source/drain region is located in the central portion of the active region 104. Two channel regions are sandwiched between the first source/drain regions and the second source/drain region.

The semiconductor memory structure 100 further includes multiple word lines (WLs) embedded in the substrate 102. The word lines WL extend in the second direction D2 and pass through the channel regions of the active region 104. The word lines WL act as gate structures, combining with the source/drain regions of the active region 104 to form transistors.

The semiconductor memory structure 100 further includes multiple bit line structures (BLs) disposed over the substrate 102. The bit line structures BL extend in the third direction D3 and are electrically connected to the second source/drain regions at the central portions of the active regions 104. Each of the bit line structures BL includes contact plugs (not shown) corresponding to and landing on the second source/drain regions of the active regions 104.

The semiconductor memory structure 100 further includes contact plugs 110 and conductive pads (or landing pads) 112. The contact plugs 110 are disposed on the first source/drain regions at the end portions of the active regions 104, and the conductive pads 112 are disposed on the contact plugs 110. The semiconductor memory structure 100 further includes a dielectric structure 114 surrounding the active regions 104, the word lines WL, the bit line structures BL, the contact plugs 110, and the conductive pads 112. The dielectric structure 114 may include one or more dielectric layers, such as silicon oxide (SiO), silicon nitride (SiN), silicon oxynitride (SiON), multilayers thereof, and/or combinations thereof.

The semiconductor memory structure 100 also includes multiple capacitor structures CA and a protection layer 132. The capacitor structures CA are disposed over the conductive pads 112, and the protection layer 132 surrounds the capacitor structures CA. The capacitor structures CA are coupled to the underlying transistors, functioning as the unit cells of the DRAM device. Each of the capacitor structures CA includes a bottom electrode layers 120, a capacitor dielectric film 122 disposed on the bottom electrode layers 120, and a top electrode layer 130 disposed on the capacitor dielectric film 122. The bottom electrode layers 120 are electrically connected to the first source/drain regions of the active regions 104 through the conductive pads 112 and the contact plugs 110.

The bottom electrode layers 120 have cup-shaped contours. In the plan view, the bottom electrode layers 120 are annular (e.g., circular), while in the cross-sectional view, the bottom electrode layers 120 have U-shaped profiles. The bottom electrode layers 120 of some capacitor structures CA overlap with the first source/drain regions electrically connected thereto. The bottom electrode layers 120 of other capacitor structures CA do not overlap (or is offset by a certain distance) with the first source/drain region electrically connected thereto.

The bottom electrode layers 120 has an inner surface 122S1 facing inward and an outer surface 122S2 facing outward. The capacitor dielectric film 122 and the top electrode layer 130 extend along the inner surface 122S1 and the outer surface 122S2 of the bottom electrode layers 120. As a result, in the plan view, the capacitor structures CA has a concentric circular structure, sequentially consisting of the top electrode layer 130/capacitor dielectric film 122/bottom electrode layers 120/capacitor dielectric film 122/top electrode layer 130 from the inside out or from the outside in. The capacitor dielectric film 122 and the top electrode layer 130 partially fill the interiors of the cup-shaped contours of the bottom electrode layers 120. The protection layer 132 includes a portion extending into the bottom electrode layers 120 and filling the remaining portions of the interiors of the cup-shaped contours.

The capacitor dielectric film 122 is a multilayer structure with high dielectric constant (high-k) dielectric materials. In some embodiments, the multilayer structure of the capacitor dielectric film 122 may be or include zirconium oxide (ZrO₂)/aluminum oxide (Al₂O₃)/zirconium oxide (ZrO₂) to achieve high permittivity and low leakage current characteristics. However, such the multilayer structure of zirconium oxide (ZrO₂)/aluminum oxide (Al₂O₃)/zirconium oxide (ZrO₂) may generate high tensile stress, which may lead to distortion or tilting of the capacitors. Therefore, the risk of short circuits between capacitors may increase, thereby reducing the manufacturing yield of the semiconductor memory device.

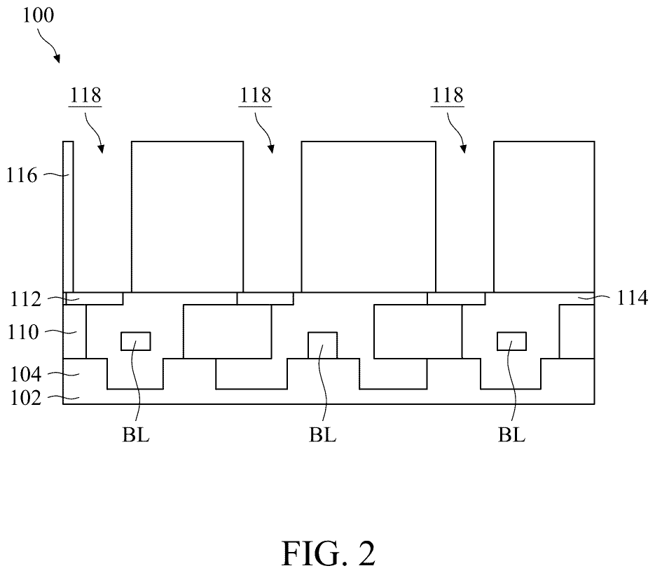

Embodiments of the present disclosure provide a semiconductor memory structure and a method for forming the same to reduce the tensile stress of the capacitor dielectric film, thereby reducing the risk of distortion or tilting of the capacitors. FIGS. 2 to 5 and FIG. 7 are cross-sectional views illustrating the formation of the semiconductor memory structure 100 at various intermediate stages, in accordance with some embodiments of the present disclosure. FIGS. 2 to 5 and FIG. 7 correspond to line I-I in FIG. 1A.

A sacrificial layer 116 is formed over the dielectric structure 114 and the conductive pads 112, as shown in FIG. 2. In some embodiments, the sacrificial layer 116 may include one or more dielectric materials, such as silicon oxide (SiO), silicon nitride (SiN), silicon oxynitride (SiON), multilayers thereof, other suitable materials, and/or combinations thereof.

The sacrificial layer 116 is patterned to form openings 118. The patterning process may include forming a patterned mask layer (not shown) over the sacrificial layer 116 using photolithography process followed by an etching process. The openings 118 correspond to and expose the conductive pads 112. In the plan view, the openings 118 have circular profiles.

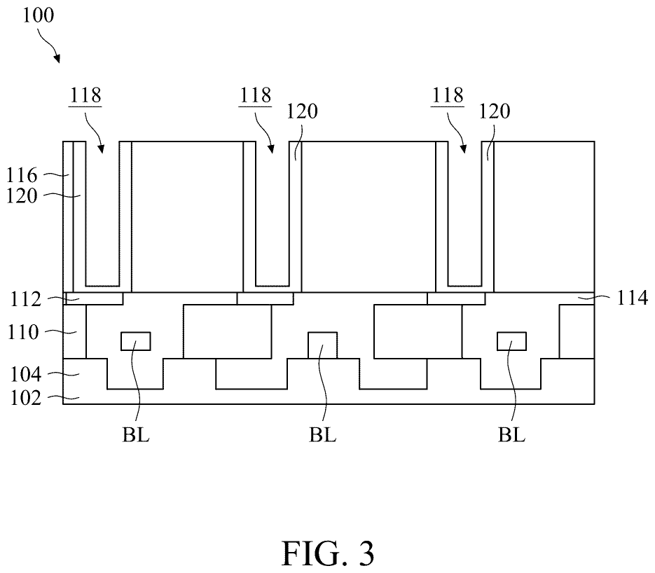

Bottom electrode layers 120 are formed in the openings 118, as shown in FIG. 3. The bottom electrode layers 120 extend along the bottom and the sidewalls of the openings 118. The bottom electrode layers 120 may be made of conductive materials such as metal nitrides (e.g., titanium nitride (TiN) or tantalum nitride (TaN)), metal materials (e.g., tungsten (W), aluminum (Al), copper (Cu), cobalt (Co), or ruthenium (Ru)), multilayers thereof, and/or combinations thereof. The formation of the bottom electrode layers 120 includes conformally depositing a conductive material for the bottom electrode layers 120, followed by an etching process.

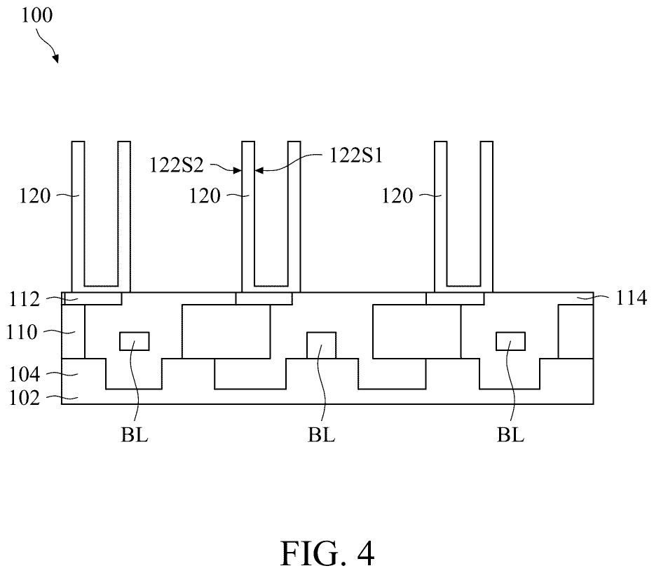

The sacrificial layer 116 is removed to expose the outer surfaces 122S2 of the bottom electrode layers 120 and the upper surface of the dielectric structure 114, as shown in FIG. 4. The removal process may be an etching process.

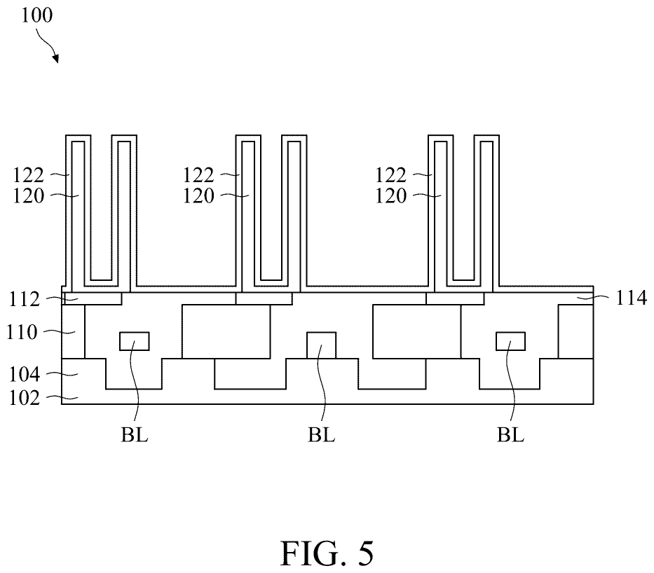

The capacitor dielectric film 122 is formed above the bottom electrode layers 120, as shown in FIG. 5. The capacitor dielectric film 122 conformally extends on the upper surface of the dielectric structure 114, and the outer surfaces 122S2, the top surfaces, the inner surfaces 122S1 and lower surfaces of the bottom electrode layers 120. In some embodiments, the capacitor dielectric film 122 is a tri-layer structure of zirconium oxide (ZrO₂)/aluminum oxide (Al₂O₃)/zirconium oxide (ZrO₂).

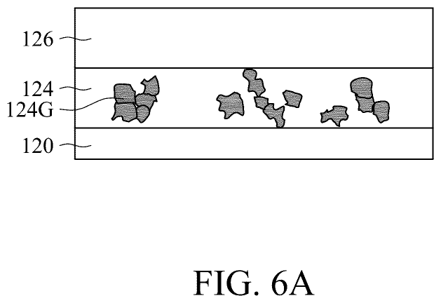

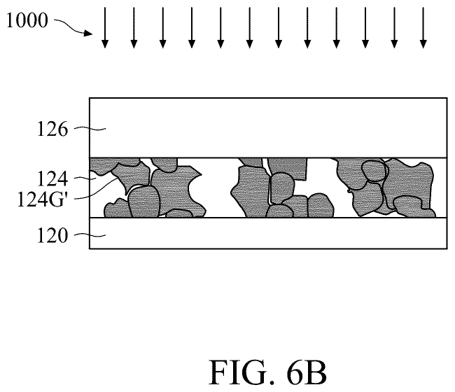

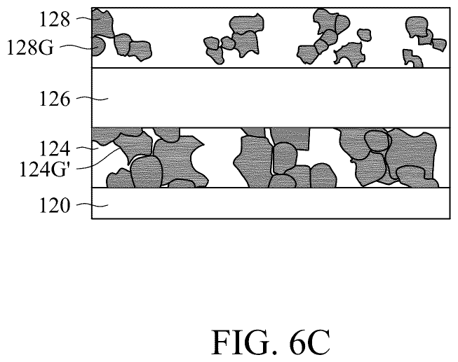

FIGS. 6A to 6C are schematic diagrams illustrating the details of the formation of the capacitance dielectric film 122, in accordance with some embodiments. The semiconductor memory structure 100 are placed in a deposition tool. A first high-k dielectric material 124 and a second high-k dielectric material 126 are sequentially deposited on the bottom electrode layers 120, as shown in FIG. 6A. The first high-k dielectric material 124 is a layer of zirconium oxide (ZrO₂), and the second high-k dielectric material 126 is a layer of aluminum oxide (Al₂O₃). In some embodiments, the deposition process may be an atomic layer deposition (ALD) process. The steps of depositing the first high-k dielectric material 124 and depositing the second high-k dielectric material 126 may be performed consecutively using the same deposition tool.

For example, the step of depositing the first high-k dielectric material 124 includes performing 25 to 150 deposition cycles using a zirconium-containing precursor (e.g., CpZr(NMe₂)₃ and/or ZrCl₄) and an oxygen-containing precursor (e.g., O₃). The step of depositing the second high-k dielectric material 126 includes performing 3 to 20 deposition cycles using an aluminum-containing precursor (e.g., trimethylaluminum (TMA)) and an oxygen-containing precursor (e.g., O₃).

In some embodiments, the as-deposited first high-k dielectric material 124 has a crystalline portion and an amorphous portion. The crystalline portion is composed of grains 124G. For example, the grains 124G have an average size of about 0.1 nanometers (nm). In some other embodiments, the entire as-deposited first high-k dielectric material 124 is amorphous.

Once the step of depositing the second high-k dielectric material 126 is completed, the semiconductor memory structure 100 is removed from the deposition tool. Subsequently, the semiconductor memory structure 100 is placed in a thermal treatment tool. An annealing process 1000 is performed on the first high-k dielectric material 124 and the second high-k dielectric material 126, as shown in FIG. 6B. The annealing process 1000 can adequately release the tensile stress between the first high-k dielectric material 124 and the second high-k dielectric material 126. Thus, the risk of short circuits between the capacitors may be reduced, thereby improving the manufacturing yield of the semiconductor memory device.

In some embodiments, the annealing process 1000 is performed at a temperature in a range from about 400° C. to about 600° C. and in a process atmosphere containing N₂. If the annealing temperature is too low or the annealing time is too short, the stress between the first high-k dielectric material 124 and the second high-k dielectric material 126 may not be adequately released. If the annealing temperature is too high or the annealing time is too long, excessive interdiffusion between aluminum atoms from the second high-k dielectric material 126 and zirconium atoms from the first high-k dielectric material 124 may occur. This could lead to a significant increase in the leakage rate of the capacitor dielectric film 122, reducing the reliability of the semiconductor memory device.

During the annealing process 1000, the first high-k dielectric material 124 undergoes grain growth, and the degree of crystallinity of the first high-k dielectric material 124 increases. The grown grains 124G′ have an average size ranging from about 0.1 nm to about 1 nm.

Once the annealing process 1000 is completed, the semiconductor memory structure 100 is removed from the thermal treatment tool. The semiconductor memory structure 100 is then placed in a deposition tool, and the third high-k dielectric material 128 is deposited, as shown in FIG. 6C. The third high-k dielectric material 128 is a layer of zirconium oxide. In some embodiments, the deposition process may be an atomic layer deposition (ALD) process.

For example, the deposition of the third high-k dielectric material 128 includes performing 10 to 65 deposition cycles using a zirconium precursor (e.g., CpZr(NMe₂)₃ and/or ZrCl₄) and an oxygen precursor (e.g., O₃). The number of deposition cycles for the third high-k dielectric material 128 may be less than the number of deposition cycles for the first high-k dielectric material 124. The thickness of the third high-k dielectric material 128 may be less than the thickness of the first high-k dielectric material 124.

In some embodiments, the as-deposited third high-k dielectric material 128 has a crystalline portion and an amorphous portion. The crystalline portion is composed of grains 128G. For example, the grains 128G have an average size of about 0.1 nm. In some other embodiments, the entire as-deposited third high-k dielectric material 128 is amorphous.

The degree of crystallinity of the third high-k dielectric material 128 is lower than that of the annealed first high-k dielectric material 124, and the average size of grains 128G is smaller than the average size of grains 124G′. In some embodiments, the ratio of the average size of grains 128G to the average size of grains 124G′ ranges from about 0.1 to about 0.8.

During the aforementioned annealing process 1000, zirconium atoms from the first high-k dielectric material 124 diffuse into the second high-k dielectric material 126, causing the second high-k dielectric material 126 to contain zirconium. As a result, the second high-k dielectric material 126 has a higher zirconium concentration at the interface between the first high-k dielectric material 124 and the second high-k dielectric material 126 than a zirconium concentration at the interface between the third high-k dielectric material 128 and the second high-k dielectric material 126.

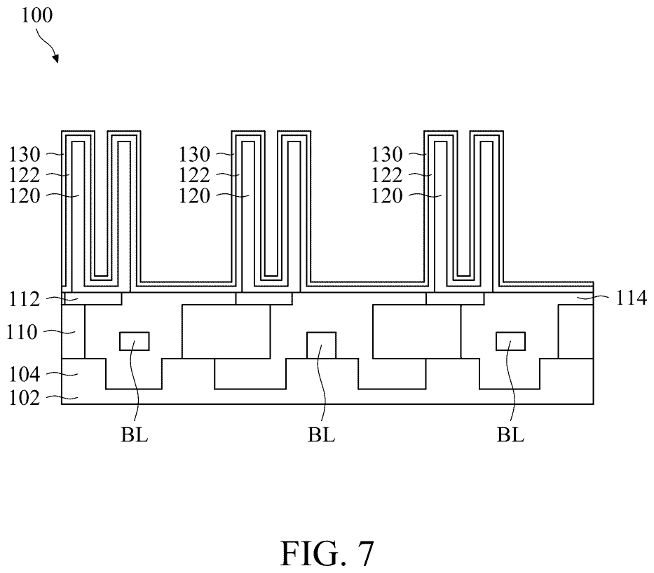

Referring to FIG. 7, once the deposition of the third high-k dielectric material 128 is completed, a top electrode layer 130 is conformally formed over the third high-k dielectric material 128 of the capacitor dielectric film 122. The top electrode layer 130 may be made of conductive materials such as metal nitrides (e.g., titanium nitride (TiN) or tantalum nitride (TaN)), metals (e.g., tungsten (W), aluminum (Al), copper (Cu), cobalt (Co), or ruthenium (Ru)), multilayers thereof, and/or combinations thereof.

It should be noted that, after the deposition of the third high-k dielectric material 128, no additional thermal treatment (such as an annealing process) is performed on the capacitor dielectric film 122. This is because an additional thermal treatment may lead to interdiffusion at both interfaces of the tri-layer structure of the capacitor dielectric film 122 (i.e., the interface between the high-k dielectric materials 126 and 124, and the interface between the dielectric constant dielectric material 126 and 128). This could result in a significant increase in the leakage rate of the capacitor dielectric film 122.

Subsequently, a protection layer 132 is formed over the top electrode layer 130, as shown in FIG. 1B. In some embodiments, the protection layer 132 is a semiconductor material, such as SiGe.

As described above, the embodiments of the present disclosure provide a semiconductor memory structure and the method for forming the same. The annealing process performed after the deposition of the second high-k dielectric material 126 may adequately release the stress in the capacitor dielectric film. Consequently, the risk of short circuits between capacitors may be reduced, thereby improving the manufacturing yield of the semiconductor memory device.

While the disclosure has been described by way of example and in terms of the preferred embodiments, it should be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for forming a semiconductor memory structure, comprising:
forming a bottom electrode layer over an active region;
depositing a first high-k dielectric material on the bottom electrode layer;
depositing a second high-k dielectric material on the first high-k dielectric material;
performing an annealing process on the first high-k dielectric material and the second high-k dielectric material;
after the annealing process, depositing a third high-k dielectric material on the second high-k dielectric material; and
forming a top electrode layer on the third high-k dielectric material.

2. The method for forming the semiconductor memory structure as claimed in claim 1, wherein a temperature of the annealing process is in a range from about 400° C. to about 600° C.

3. The method for forming the semiconductor memory structure as claimed in claim 1, wherein the first high-k dielectric material and the third high-k dielectric material are zirconium oxide, and the second high-k dielectric material is aluminum oxide.

4. The method for forming the semiconductor memory structure as claimed in claim 1, wherein during the annealing process, zirconium atoms from the first high-k dielectric material diffuse into the second high-k dielectric material.

5. The method for forming the semiconductor memory structure as claimed in claim 1, wherein before the annealing process, grains of the first high-k dielectric material have a first average size, and after the annealing process, the grains of the first high-k dielectric material have a second average size that is greater than the first average size.

6. The method for forming the semiconductor memory structure as claimed in claim 5, wherein grains of the third high-k dielectric material have a third average size that is smaller than the second average size.

7. The method for forming the semiconductor memory structure as claimed in claim 1, wherein the deposition of the first high-k dielectric material and the deposition of the second high-k dielectric material are performed consecutively using in a same deposition tool.

8. The method for forming the semiconductor memory structure as claimed in claim 1, wherein the annealing process is performed in a thermal treatment tool, and during the annealing process, a surface of the second high-k dielectric material is exposed to a process atmosphere.

9. The method for forming the semiconductor memory structure as claimed in claim 1, further comprising.
forming a dielectric structure around the active region;
forming a sacrificial layer above the dielectric structure, wherein the sacrificial layer has an opening, and the bottom electrode layer is formed in the opening;
removing the sacrificial layer to expose side surfaces of the bottom electrode layer; and
forming a protection layer around the top electrode layer.

10. The method for forming the semiconductor memory structure as claimed in claim 1, further comprising:
forming a contact plug on a source/drain region of the active region; and
forming a conductive pad over the contact plug, wherein the bottom electrode layer is electrically connected to the source/drain region of the active region through the conductive pad and the contact plug.

11. The method for forming the semiconductor memory structure as claimed in claim 1, wherein forming the first high-k dielectric material comprises performing a first atomic layer deposition with first deposition cycles, and forming the third high-k dielectric material comprises performing a second atomic layer deposition with second deposition cycles, and number of first deposition cycles is greater than number of second deposition cycles.

12. A semiconductor memory structure, comprising:
a transistor disposed over a substrate;
a bottom electrode layer disposed over the transistor and electrically connected to a first source/drain region of the transistor;
a capacitor dielectric film comprising, sequentially disposed over the bottom electrode layer, a first high-k dielectric material, a second high-k dielectric material and a third high-k dielectric material, wherein the second high-k dielectric material contains zirconium and has:
a first zirconium concentration at an interface between the first high-k dielectric material and the second high-k dielectric material, and
a second zirconium concentration at an interface between the third high-k dielectric material and the second high-k dielectric material, wherein the first zirconium concentration is higher than the second zirconium concentration; and
a top electrode layer disposed over the capacitor dielectric film.

13. The semiconductor memory structure as claimed in claim 12, wherein in a plan view, the bottom electrode layer has an annular profile.

14. The semiconductor memory structure as claimed in claim 13, wherein the capacitor dielectric film extends along an inner surface and an outer surface of the annular profile of the bottom electrode layer.

15. The semiconductor memory structure as claimed in claim 13, further comprising:
a protection layer surrounding the top electrode layer, wherein the protection layer includes a portion in the annular profile of the bottom electrode layer.

16. The semiconductor memory structure as claimed in claim 12, wherein grains of the first high-k dielectric material have a first average size, and grains of the third high-k dielectric material have a second average size, and the first average size is greater than the second average size.

17. The semiconductor memory structure as claimed in claim 12, further comprising:
a contact plug disposed on the first source/drain region of the transistor; and
a conductive pad disposed on the contact plug, wherein the bottom electrode layer is disposed on the conductive pad.

18. The semiconductor memory structure as claimed in claim 12, wherein the first high-k dielectric material has a first degree of crystallinity, and the third high-k dielectric material has a second degree of crystallinity that is less than the first degree of crystallinity.

19. The semiconductor memory structure as claimed in claim 12, further comprising:
a bit line structure extending over the substrate in a first direction and electrically connected to a second source/drain region of the transistor.

20. The semiconductor memory structure as claimed in claim 19, wherein the transistor has a gate structure disposed in the substrate, and the gate structure extends in a second direction perpendicular to the first direction.
